(19) United States
(12) Patent Application Publication
(10) Pub. No.: US 2018/0366631 A1
(43) Pub. Date: Dec. 20, 2018

(54) THERMOELECTRIC CONVERSION MODULE AND METHOD FOR MANUFACTURING THERMOELECTRIC CONVERSION MODULE

(71) Applicant: Murata Manufacturing Co., Ltd., Nagaokakyo-shi (JP)

(72) Inventors: Osamu Chikagawa, Nagaokakyo-shi (JP); Sachiko Hayashi, Nagaokakyo-shi (JP); Yoshiyuki Yamashita, Nagaokakyo-shi, (JP)

(21) Appl. No.: 16/111,368

(22) Filed: Aug. 24, 2018

Related U.S. Application Data
(63) Continuation of application No. PCT/JP2017/001566, filed on Jan. 18, 2017.

(30) Foreign Application Priority Data
Mar. 31, 2016 (JP) 2016-071966

(51) Int. Cl. H01L 35/22; H01L 35/34; H01L 35/08; H01L 27/16

(52) U.S. Cl. CPC H01L 35/22; H01L 27/16; H01L 35/08; H01L 35/34

(57) ABSTRACT

A thermoelectric conversion module includes a plurality of thermoelectric conversion element and a sealing member for sealing the plurality of thermoelectric conversion elements. The thermoelectric conversion element includes a plurality of first thermoelectric conversion parts and a plurality of second thermoelectric conversion parts, being alternately disposed in a Y-axial direction. At least one of an end portion of the first thermoelectric conversion part on its −Z direction side and an end portion thereof on its +Z direction side is electrically connected to an end portion of the second thermoelectric conversion part of the adjacent other thermoelectric conversion element. The sealing member has an upper side serving as a contact surface.

### CROSS REFERENCE TO RELATED APPLICATIONS

The present application is a continuation of International application No. PCT/JP2017/001566, filed Jan. 18, 2017, which claims priority to Japanese Patent Application No. 2016-071966, filed Mar. 31, 2016, the entire contents of each of which are incorporated herein by reference.

### TECHNICAL FIELD

The present invention relates to a thermoelectric conversion module and a method for manufacturing a thermoelectric conversion module.

### BACKGROUND ART

A thermoelectric conversion module including a plurality of laminated-type thermoelectric conversion elements has been proposed in Japanese Patent Laid-Open No. H9-74227. This thermoelectric conversion module generates electricity generated in a state where a heat generating object and an object having a temperature lower than the heat generating object are in contact with each of the plurality of thermoelectric conversion elements.

Thermoelectric conversion elements vary in dimensions due to manufacturing variations and the like. When a plurality of thermoelectric conversion elements are about to be used while being brought into contact with a flat surface formed on a part of the heat generating object in the thermoelectric conversion module disclosed in the foregoing patent application, variations in dimensions of the plurality of thermoelectric conversion elements cause a gap between the thermoelectric conversion elements and the heat generating object. As a result, the thermoelectric conversion elements deteriorate in heat transfer efficiency from the heat generating object, so that a sufficient temperature difference in the thermoelectric conversion elements cannot be obtained. This causes its output voltage to be less than voltage that can be output by its specification.

### BRIEF DESCRIPTION OF THE INVENTION

The present invention is made in light of the above-mentioned circumstances and an object thereof is to provide a thermoelectric conversion module and a method for manufacturing a thermoelectric conversion module, capable of increasing output voltage.

According to an aspect of the present invention, a thermoelectric conversion module includes a plurality of thermoelectric conversion elements, each of which comprising a laminated body having first and second opposing main surfaces which are spaced from each other along a first direction and first and second opposing end surfaces which are spaced from each other along a second direction, the second direction being perpendicular to the first direction. Each of the laminated bodies comprising a plurality of first and second thermoelectric conversion parts which alternate with one another along the first direction. Each of the first and second thermoelectric conversion parts has opposed first and second end surfaces which are spaced apart along the second direction. A sealing member seals the plurality of thermoelectric conversion elements. The sealing member includes portions located on at least some of the first end surfaces of the first and second thermoelectric conversion parts and portions located on at least some of the second end surfaces of the first and second thermoelectric conversion parts.

In some embodiments, an external surface of the sealing member has a non-planar shape allowing surface contact with a heat-generating object.

In other aspects of the invention, the thermoelectric conversion module further comprises a heat transfer element provided on one of the first and second sealing member portions to either transfer heat from a heat generating object to the sealing member or to transfer heat from the sealing member to a heat radiating member. In an embodiment, the sealing member is a hardened body made of an epoxy resin. In another embodiment, the hardened body further contains an inorganic filler.

In another aspect of the invention, adjacent first and second thermoelectric parts each define a respective thermoelectric conversion part pair. Each thermoelectric conversion part pair includes a respective first thermoelectric conversion part and a respective second thermoelectric conversion part. A joint surface of the first thermoelectric part of the pair facing a joint surface of the second thermoelectric part of the pair. The thermoelectric module further comprises a plurality of insulator layers, each insulator layer being associated with a respective thermoelectric conversion part pair, each insulator being located between a first portion of the facing joint surfaces of the first and second thermoelectric conversion parts of its respective thermoelectric conversion part pair. A second portion of the facing joint surfaces of the first and second thermoelectric conversion parts of each thermoelectric part pair is directly joined to one another.

In an embodiment, each of the second thermoelectric conversion parts has an end face opposing the first or second end surface of the laminated body with a portion of a respective one of insulator layers covering the end face and being located between the end face and the first or second end surface that the end face opposes. In an embodiment, each of the second thermoelectric conversion parts is made of a metal thermoelectric conversion material.

In another aspect of the invention, each of the first thermoelectric conversion parts is made of oxide thermoelectric conversion material and each of the insulator layers is made of oxide insulator material.

In another aspect of the invention, each of the first and second thermoelectric conversion parts is planar in shape and the plane of each of the first and second thermoelectric conversion parts lies in a plane that is perpendicular to the first direction.

In an embodiment of the invention, the sealing member includes portions located on all of the first and second end surfaces of the first and second thermoelectric conversion parts.

In embodiments of the invention, the heat transfer member is formed of metal.

In embodiments of the invention, a respective heat transfer member is provided for each of the thermoelectric conversion elements. In some embodiments, the heat transfer members is formed of metal.

The invention is also directed towards a method for manufacturing a thermoelectric conversion module. IN accordance with one aspect of the method, a metal foil having first and second opposed surfaces is prepared. The first surface of the metal foil is provided with an adhesion prevention region to which a conductive paste does not adhere. The second surface of the metal foil is attached to a support substrate. A plurality of land regions are formed in the first surface of the metal foil. Each land region has a wettability relative to the conductive paste that is better than the wettability of the adhesion prevention region of the metal foil. The land regions are formed at locations where conductive parts are to be formed.

An electrode of a thermoelectric conversion element is electrically connected to one of the land regions using the conductive paste. A first sub-sealing portion which covers at least part of the first surface of the metal foil is formed and the support substrate is removed from the second surface of the metal foil. Conductive parts are formed by processing the second side of the metal foil such that the conductive parts each have first and second opposed surfaces and the first sub-sealing portion covers the first surface of the conductive parts. External electrodes are formed on the second surface of two of the plurality of conductive parts. Finally, a second sub-sealing portion is formed to cover the second surface of each of the conductive parts except for the two conductive parts on which the external electrodes are formed.

In accordance with an aspect of the invention, a temperature difference in each of the thermoelectric conversion elements comes close to a temperature difference between the heat generating object and the heat radiating member, so that output voltage increases accordingly to increase output voltage of the entire thermoelectric conversion module.

### BRIEF EXPLANATION OF DRAWINGS

FIG. 1 is a perspective view of a thermoelectric conversion module according to a first embodiment of the present invention.

FIG. 2 is a sectional view of the thermoelectric conversion module according to the first embodiment taken along line A-A of FIG. 1.

FIG. 3 is a partial sectional view of the thermoelectric conversion module according to the first embodiment.

FIG. 4 is a sectional view of a thermoelectric conversion module according to a comparative example.

FIGS. 5A-5C are sectional views illustrating steps of a method for manufacturing the thermoelectric conversion module according to the first embodiment.

FIGS. 6A-6D are sectional views of yet other steps of the method for manufacturing the thermoelectric conversion module according to the first embodiment.

FIG. 7 is a perspective view of a thermoelectric conversion module according to a second embodiment of the present invention.

FIG. 8 is a sectional view of the thermoelectric conversion module according to the second embodiment taken along line B-B of FIG. 7.

FIGS. 9A and 9B are sectional views of steps of a method for manufacturing the thermoelectric conversion module according to the second embodiment.

FIGS. 10A-10C are sectional views of other steps of the method for manufacturing the thermoelectric conversion module according to the second embodiment.

FIGS. 11A-11C are sectional views of yet other steps of the method for manufacturing the thermoelectric conversion module according to the second embodiment.

FIGS. 12A-12C are sectional views of yet other steps of the method for manufacturing the thermoelectric conversion module according to the second embodiment.

FIG. 13 is a perspective view of a thermoelectric conversion module according to a modified example of the present invention.

FIG. 14 is a sectional view of the thermoelectric conversion module according to the modified example taken along line C-C of FIG. 13.

FIG. 15 is a partial sectional view of the thermoelectric conversion module according to the modified example.

FIG. 16 is a perspective view of the thermoelectric conversion module according to another modified example.

FIG. 17 is a perspective view of the thermoelectric conversion module according to yet another modified example.

FIGS. 18A and 18B are perspective views of the thermoelectric conversion module according to yet another modified example.

FIG. 19 is a perspective view of the thermoelectric conversion module according to yet another modified example.

FIG. 20 is a perspective view of the thermoelectric conversion module according to yet another modified example.

FIG. 21 is a partial sectional view of the thermoelectric conversion module according to yet another modified example.

### DESCRIPTION OF PREFERRED EMBODIMENTS

### First Embodiment

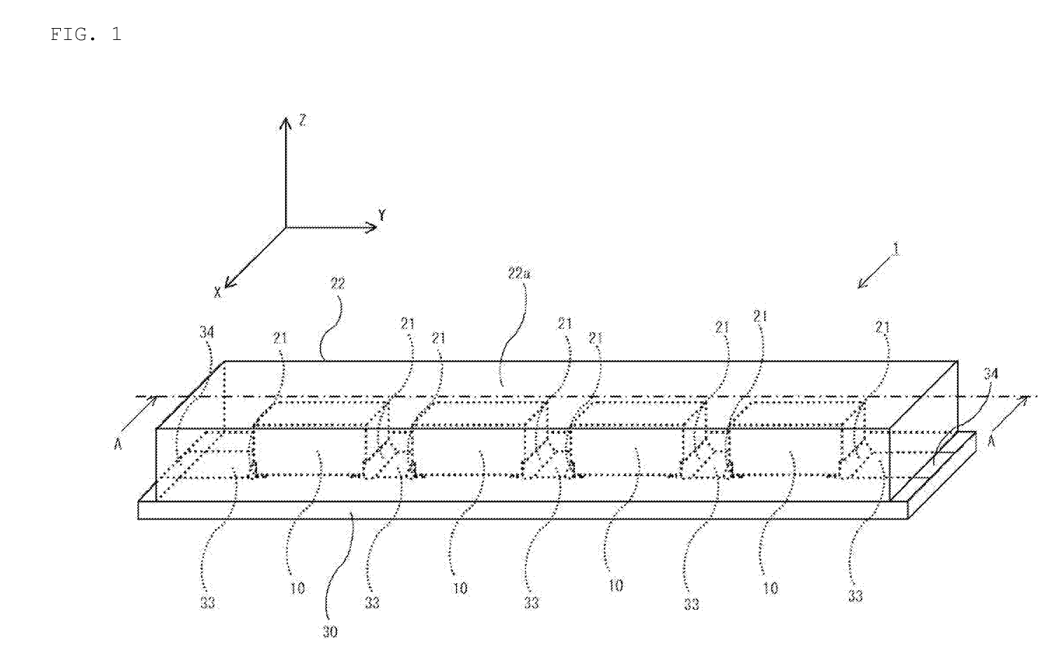

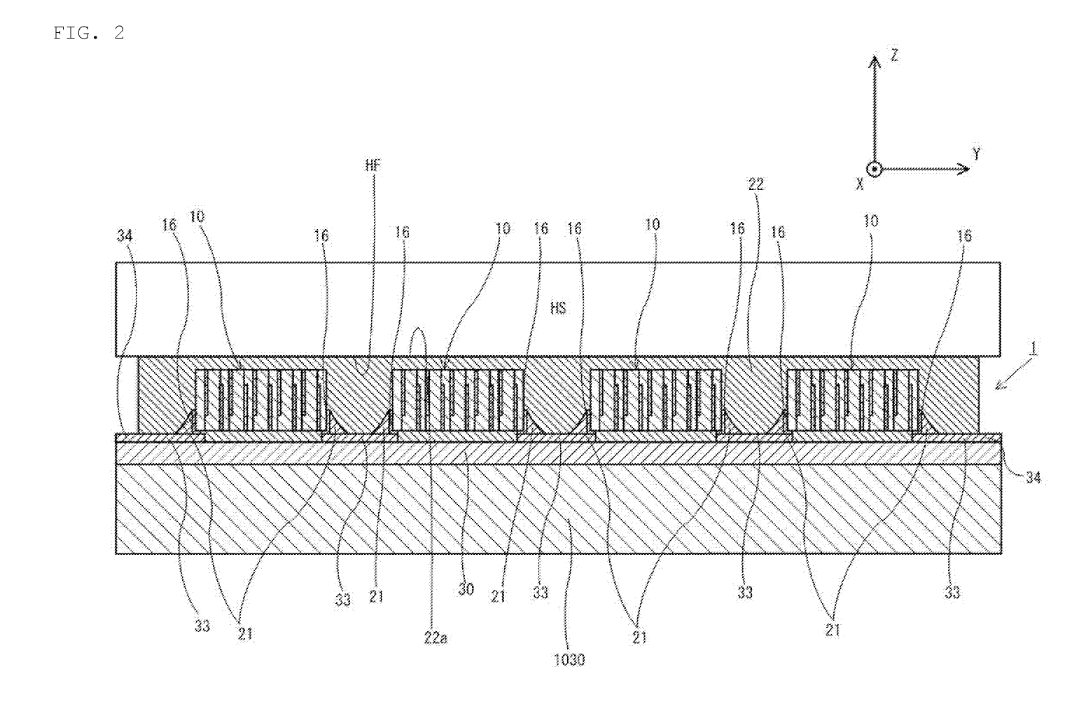

The thermoelectric conversion module 1 according to a first embodiment of the invention has a structure in which a plurality of thermoelectric conversion elements mounted on a substrate are entirely covered with a sealing member. As illustrated in FIG. 1, the thermoelectric conversion module 1 includes a substrate 30, a plurality (four in FIG. 1) of thermoelectric conversion elements 10 and a sealing member 22 covering the thermoelectric conversion elements 10. As illustrated in FIG. 2, upper surface of the sealing member 22 contacts a mounting surface HF of a heat generating object HS. The heat generating object HS can be, for example, a metal flat plate that is thermally coupled to a waste heat pipe installed in a factory or the like. In the following description, a +Z direction (see the coordinate system illustrated in the drawings) in FIG. 1 is referred to as an upward direction and a −Z direction is referred to as a downward direction.

The substrate 30 is made of SiN or the like, and is provided on its upper surface with conductive portions 33 which allow the four thermoelectric conversion elements 10 to be connected in series. The substrate 30 is disposed on a metal heat sink (heat radiating member) 1030. The conductive portions 33 which are positioned at respective opposite interval ends of the thermoelectric conversion module in a Y-axis direction partially serve as external electrodes 34 (FIG. 1) which can be connected to an external device (not illustrated) via lead wires (not illustrated). The conductive portions 33 are preferably made of metal such as Cu, Al, Ni, or the like.

As illustrated in FIGS. 1 and 2, the plurality of thermoelectric conversion elements 10 are linearly disposed on the upper surface of the substrate 30. Hereinafter, an array direction of the plurality of thermoelectric conversion elements 10 is referred to as a Y-axis direction.

As illustrated in FIG. 3, each of the thermoelectric conversion elements 10 includes a plurality of first thermoelectric conversion parts 113, a plurality of second thermoelectric conversion parts 111, a plurality of insulator layers 115, and electrodes 16. The plurality of first thermoelectric conversion parts 113 and the plurality of second thermoelectric conversion parts 111 are alternately disposed and bonded in the Y-axis direction. Abutting first and second thermoelectric conversion parts 113 and 111 are directly bonded to each other along a portion of their opposed bonding surfaces. The remainder of the bonding surfaces are bonded to a respective insulator layer 115 interposed between opposed bonding surfaces. Specifically, a lower end (as viewed in FIG. 3) portion 113a of the first thermoelectric conversion part 113 is electrically connected to a lower end portion 111a of the second thermoelectric conversion part 111 located adjacent to the first thermoelectric conversion part 113 in a −Y direction (i.e., in one direction of the array direction). An upper end portion 113b (again as viewed in FIG. 3) of each first thermoelectric conversion part 113 is electrically connected to an upper end portion 111b of the second thermoelectric conversion part 111 adjacent to the first thermoelectric conversion part 113 in a +Y direction (i.e., in the other direction of the array direction).

The first thermoelectric conversion parts 113 are, for example, an N-type semiconductor and are made of oxide thermoelectric conversion material. The oxide thermoelectric conversion material includes complex oxide having a perovskite structure, being expressed by a composition formula: ATiO3. In this composition formula: ATiO3, A includes Sr. In ATiO3, A may be acquired by substituting Sr with La in La1−xSrx in the range of 0≤x<0.2, and thus (Sr0.965La0.03)TiO3 may be used, for example.

The second thermoelectric conversion parts 111 are, for example, a P-type semiconductor material made of metal thermoelectric conversion material. The metal thermoelectric conversion material includes NiMo and complex oxide having a perovskite structure, being expressed by a composition formula: ATiO3. Such a composition as described above is defined as a P-type semiconductor. In this composition formula: ABO3, A includes Sr. In ATiO3, A may be acquired by substituting Sr with La in La1−xSrx in the range of 0≤x<0.2, and thus (Sr0.965La0.03)TiO3 may be used, for example.

The insulator layers 115 are each interposed between a respective adjacent pair of first and second thermoelectric conversion parts 113 and 111 such that each pair of first and second thermoelectric conversion parts 113 and 111 are laminated together with a respective insulator layer 115 interposed therebetween. The insulator layers 115 are preferably made of oxide insulating material having electrical insulation properties. As this oxide insulator material, ZrO₂ (yttria-stabilized zirconia) to which Y₂O₃ is added as a stabilizer is used, for example.

As illustrated in FIG. 3, a pair of electrodes 16 are electrically connected to a corresponding one of the left most and right most (as viewed in FIG. 3) second thermoelectric conversion parts 111, respectively. Stated otherwise, the right most electrode 16 positioned at the end in the +Y direction of the plurality of second thermoelectric conversion parts 111, and the left most second thermoelectric conversion part 111 positioned at the end in the −Y direction thereof. The electrode 16 that is positioned on the +Y direction side of the thermoelectric conversion element 10 has a reverse L-shaped section covering a portion of the vertical surface of the right most second thermoelectric conversion part 111 and a portion of the lower end surface (surface on a −Z direction side) of the right most second thermoelectric conversion part 111 positioned at the end in the +Y direction (all as viewed in FIG. 3). In addition, the electrode 16 positioned on the −Y direction side of the thermoelectric conversion element 10 has an L-shaped section covering a portion of the vertical surface of the left most second thermoelectric conversion part 111 and a portion of the lower end surface of the left most second thermoelectric conversion part 111 positioned at the end of the thermoelectric conversion element 10 in the −Y direction. The electrodes 16 preferably include an underlayer made of Ni, and a contact layer covering the underlayer. The contact layer preferably has a laminated structure of a Ni layer and a Sn layer. The Ni layer has a thickness set to 3 μm to 5 μm, and the Sn layer has a thickness set to 4 μm to 6 μm. The electrode 16 and the conductive portion 33 of the substrate 30 are preferably bonded to each other with a conductive member 21 interposed therebetween. The conductive member 21 is preferably made of metal such as solder.

The sealing member 22 preferably has a rectangular parallelepiped outer shape and is disposed so as to cover the upper surface of the substrate 30 to seal the plurality of thermoelectric conversion elements 10. The sealing member 22 is provided on its upper side with a contact surface (heated portion) 22a that is to be thermally coupled to the heat generating object HS. The contact surface 22a preferably has a shape allowing surface contact with the mounting surface HF of the heat generating object HS. The contact surface 22a preferably has a ten-point mean roughness set to about 1 μm or less. The sealing member 22 is formed of a hardened body containing an epoxy resin and an inorganic filler. As the epoxy resin, it is preferable to use an epoxy resin with heat resistance as excellent as possible. Representative examples of epoxy resin of this type include a polyaromatic epoxy resin, specifically, a phenol novolac type epoxy resin, an o-cresol novolac type epoxy resin, and the like. These types of epoxy resin are not plastically deformed within a range with an upper limit temperature of about 250° C. Examples of the inorganic filler include fine particles of SiO2, Al2O3, MgO, and the like.

Evaluated results of power generation performance of the thermoelectric conversion module 1 will now be described. The inventors evaluated the amount of power generation of the thermoelectric conversion element 10 according to the present embodiment and a thermoelectric conversion element according to a comparative example described below.

As the thermoelectric conversion module 1 for evaluation according to the present embodiment, a module having four thermoelectric conversion elements 10 with a rated output voltage of 63 mV was used. An average value of distances between an upper surface of the sealing member 22 of the thermoelectric conversion module 1 and upper surfaces of the respective thermoelectric conversion elements 10 was 0.2 mm.

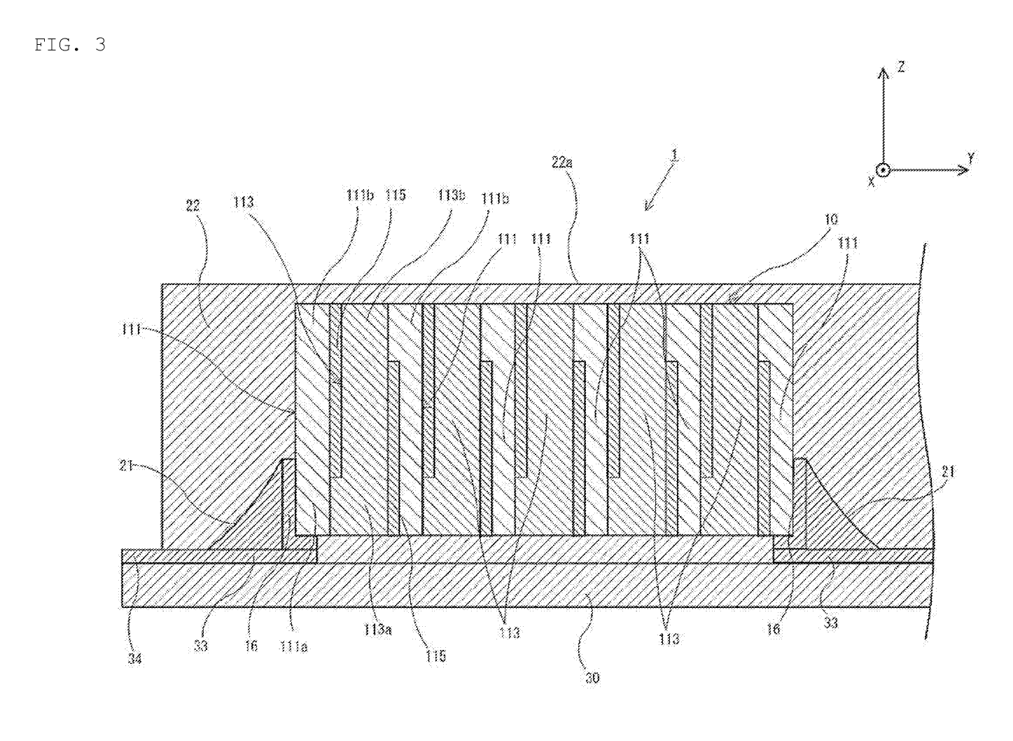

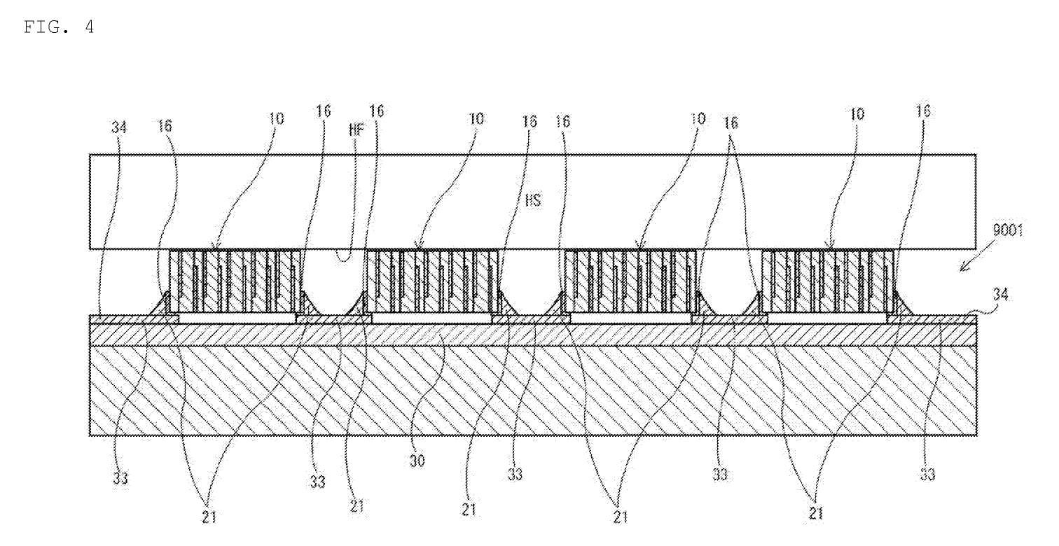

As illustrated in FIG. 4, a thermoelectric conversion module 9001 according to the comparative example also has four thermoelectric conversion elements 10 with an output voltage of 63 mV as with the thermoelectric conversion module 1. The thermoelectric conversion module 9001 has a structure similar to that of the thermoelectric conversion module 1 except that no sealing member is provided.

To evaluate power generation performance, ten of each of thermoelectric conversion modules 1 and 9001 for evaluation were prepared, and output voltage was measured for each of them. The output voltage was measured under conditions where the heat generating object in contact with an upper side of the thermoelectric conversion module 1 or 9001 was maintained at a temperature of 30° C. and the substrate 30 was maintained at a temperature of 20° C.

As a result of measurement of the output voltage, while the thermoelectric conversion module 9001 had an average value of 102 mV of the output voltage, the thermoelectric conversion module 1 had an average value of 178 mV of the output voltage. As described above, it was found that the output voltage of the thermoelectric conversion module 1 is higher by about 76 mV than the output voltage of the thermoelectric conversion module 9001.

It is believed that this result is achieved for the following reasons. The thermoelectric conversion module 9001 includes the thermoelectric conversion elements 10 each with a different height due to a manufacturing error or the like. This causes a gap (air layer) between an upper surface of the thermoelectric conversion element 10 with a relatively low height, and the mounting surface HF, when the thermoelectric conversion module 9001 is brought into contact with the mounting surface HF of the heat generating object HS. In this case, thermal resistance between the heat generating object HS and the thermoelectric conversion element 10 increases to reduce heat transfer efficiency from the heat generating object HS to the thermoelectric conversion element 10. As a result, a temperature difference between a lower end portion and an upper end portion of the thermoelectric conversion element 10 is less than a temperature difference between the heat generating object HS and the substrate 30, so that output voltage of the thermoelectric conversion module 9001 is low.

In contrast, because the thermoelectric conversion module 1 includes the sealing member 22 whose contact surface 22a is in surface contact with the mounting surface HF of the heat generating object HS, there is no gap between the contact surface 22a and the mounting surface HF. In addition, the sealing member 22 has a thermal conductivity which is higher than thermal conductivity of air+. As a result, heat transfer efficiency from the heat generating object HS to an upper end portion of the thermoelectric conversion element 10 is higher than that in the comparative example. This causes a temperature difference between the lower end portion and the upper end portion of the thermoelectric conversion element 10 to be close to a temperature difference between the heat generating object HS and the substrate 30, so that output voltage of thermoelectric conversion module 1 increases accordingly.

As described above, the thermoelectric conversion module 1 according to the present embodiment includes the sealing member 22 having a contact surface 22a which is thermally coupled to the heat generating object HS. This improves the efficiency of heat transfer of from the heat generating object HS to the upper end portion of each of the thermoelectric conversion elements 10 via the contact surface 22a. As a result, the temperature difference between the lower end portion and the upper end portion of each of the thermoelectric conversion elements 10 comes close to a temperature difference between the heat generating object HS and the heat sink 1030, so that output voltage increases accordingly to increase output voltage of the entire thermoelectric conversion module 1.

In addition, the thermoelectric conversion module 1 of the present embodiment includes the sealing member 22 with which the thermoelectric conversion elements 10 are covered to enable reducing of an external force to be applied to the thermoelectric conversion elements 10 when the thermoelectric conversion module 1 is attached to the heat generating object HS. This prevents (or at least reduces) breakage of a part of the thermoelectric conversion elements 10 in response to an external force applied to the thermoelectric conversion elements 10 when the thermoelectric conversion module 1 is attached to the heat generating object HS.

The thermoelectric conversion module 9001 (which does not include the sealing member 22) needs to bring the upper end surfaces of all of the plurality of thermoelectric conversion elements 10 into contact with the mounting surface HF of the heat generating object HS. This can be done, for example, by using a separate pressing mechanism for each of the plurality of thermoelectric conversion elements 10 to individually press them against the mounting surface HF of the heat generating object HS to prevent a gap from being formed between the thermoelectric conversion elements 10 and the mounting surface HF even when each of the plurality of thermoelectric conversion elements 10 is different in dimension, for example. However, this structure needs to be provided with the same number of pressing mechanisms as the number of the plurality of thermoelectric conversion elements 10, and thus as the number of the thermoelectric conversion elements 10 provided in the thermoelectric conversion module increases, structure of the thermoelectric conversion module becomes complicated.

In contrast, the thermoelectric conversion module 1 according to the present embodiment does not need to be provided with such a pressing mechanism, so that structure of the thermoelectric conversion module 1 and the process for making the thermoelectric conversion module 1 can be simplified.

Because the thermoelectric conversion module 1 according to the present embodiment includes the sealing member 22 having a contact surface 22a which is in surface contact with the mounting surface HF of the heat generating object, the contact area between the sealing member 22 and the heat generating object HS is increased and thermal coupling between the heat generating object HS and the sealing member 22 is strong.

The sealing member 22 according to the present embodiment is preferably formed of a hardened body containing an epoxy resin and an inorganic filler. This enables heat transfer efficiency from the heat generating object HS to the sealing member 22 to be secured, so that the thermal coupling between the heat generating object HS and the sealing member 22 becomes strong.

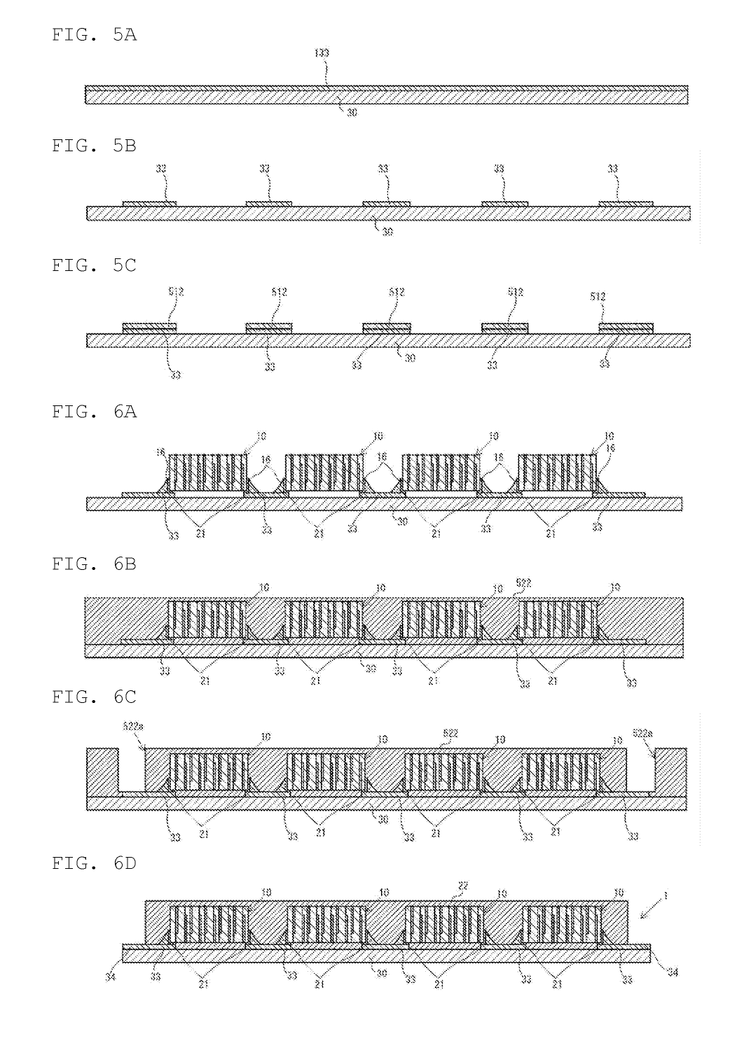

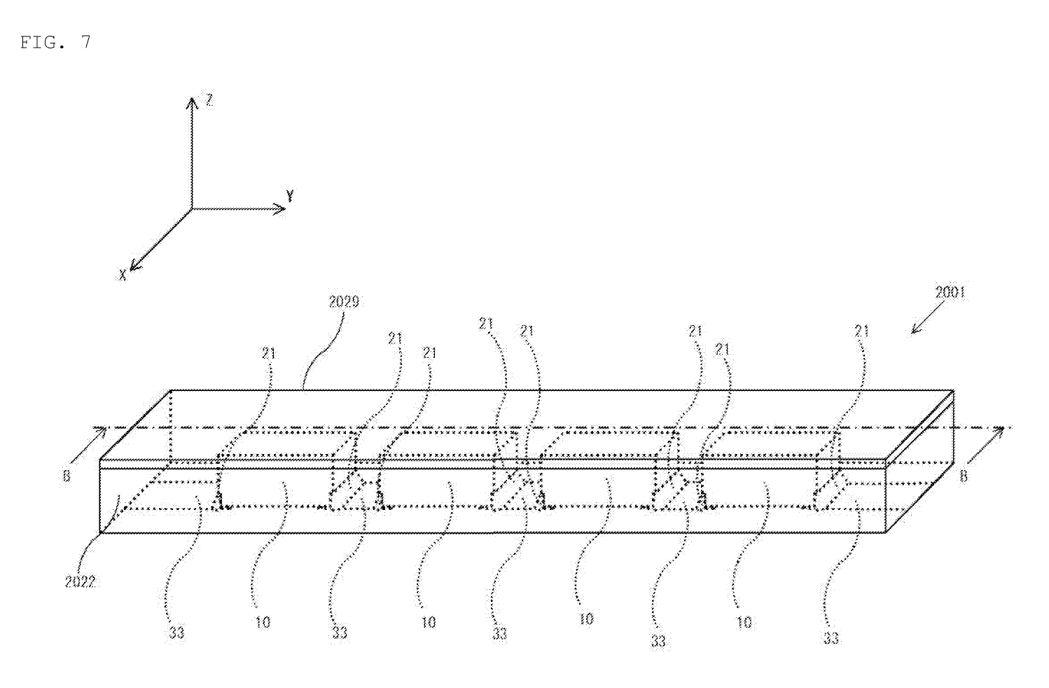

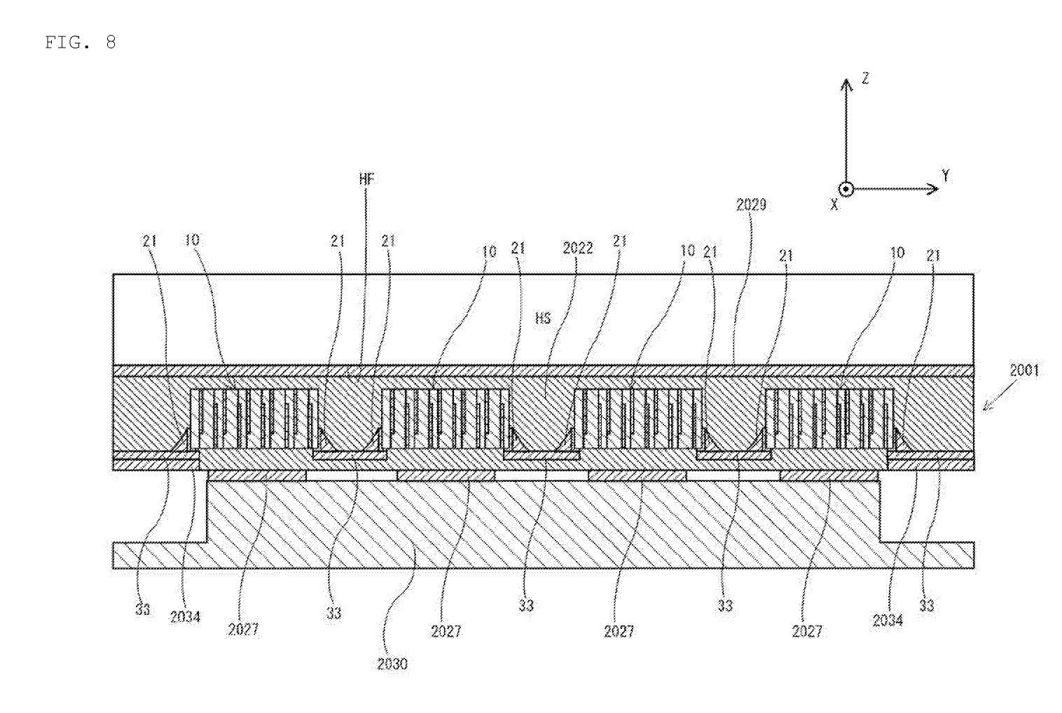

Next, a method for manufacturing the thermoelectric conversion module 1 according to the first embodiment will be described with reference to FIGS. 5A, 5B, 5C, 6A, 6B, 6C, and 6D. In this manufacturing method, a metal foil 133 which acts as a base of a conductive portion 33 is attached on a substrate 30. Thereafter a resist is formed on the metal foil 133 and is patterned to form a mask as illustrated in FIG. 5A. The metal foil is preferably made of metal such as Cu, Al, Ni, or the like. Next, the metal foil 133 is etched to form the conductive portion 33 as illustrated in FIG. 5B.

Subsequently, as illustrated in FIG. 5C, a respective metal layer 512 is formed on each conductive portion 33 using a plating method. As the plating method, there is used an electrolytic plating method for forming a metal layer by energizing a metal foil while the metal foil is immersed in an electrolytic solution, or an electroless plating method for forming a metal layer by using a reducing action when a metal foil is immersed in a plating solution containing a reducing agent. The metal layers 512 are preferably made of Ni/Au.

Next, solder is applied to each of the metal layers 512. A respective thermoelectric conversion element 10 is placed on each respective pair of adjacent conductive portions 33 such that the electrodes 16 of the respective thermoelectric conversion element 10 are brought into contact with the metal layers 512 of the two adjacent conductive portions 33 with the solder interposed therebetween. A reflow process is then performed with the result that the solder forms an alloy with the metal layer 512 and the solder creeps up to a side surface of the electrode 16 of the thermoelectric conversion element 10 to form a conductive member 21 as illustrated in FIG. 6A. While not illustrated, a part of the metal layer 512 which is not alloyed with the solder is provided on the conductive portion 33.

Subsequently, a structure composed of the substrate 30, the conductive portion 33, the conductive member 21, and the thermoelectric conversion element 10 is placed in a metal mold for molding. Then, the metal mold is filled with sealing material using a transfer molding method or a potting method. As described above, the sealing material preferably contains an epoxy resin and an inorganic filler. At this time, the sealing material also enters a gap between a lower surface of the thermoelectric conversion elements 10 and an upper surface of the substrate 30. Then, the sealing material is heated to form a hardened body. In this way, a sealing member 522 is formed on the conductive portion side 33 of the substrate 30 as illustrated in FIG. 6B.

After that, a pair of grooves 522a is formed in portions of the sealing member 522 corresponding to external electrodes 34 to expose the external electrodes 34, as illustrated in FIG. 6C.

Next, the substrate 30 and the sealing member 522 are divided into individual pieces by using a well-known dicing technique to complete a thermoelectric conversion module 1 as illustrated in FIG. 6D.

A thermoelectric conversion module including no sealing member 22 for sealing the thermoelectric conversion element 10 needs to equalize dimensions of a respective plurality of thermoelectric conversion elements 10 in the Z-axis direction to bring upper end surfaces of all of the plurality of thermoelectric conversion elements 10 into contact with a mounting surface HF of the thermoelectric conversion module of a heat generating object HS. Thus, this type of thermoelectric conversion module needs a step of polishing an upper end surface of each of the plurality of thermoelectric conversion elements to equalize the dimensions of the respective plurality of thermoelectric conversion elements 10 in the Z-axis direction after the plurality of thermoelectric conversion elements 10 is fixed to the substrate 30. Thus, stress is applied to the thermoelectric conversion element 10 to polish the thermoelectric conversion element 10, so that a part of the thermoelectric conversion element 10 may be damaged.

In contrast, the method for manufacturing the thermoelectric conversion element 10 according to the present embodiment does not include the step of polishing the thermoelectric conversion element 10. This makes it possible to prevent damage to the thermoelectric conversion elements 10 due to the polishing of the thermoelectric conversion element 10.

### Second Embodiment

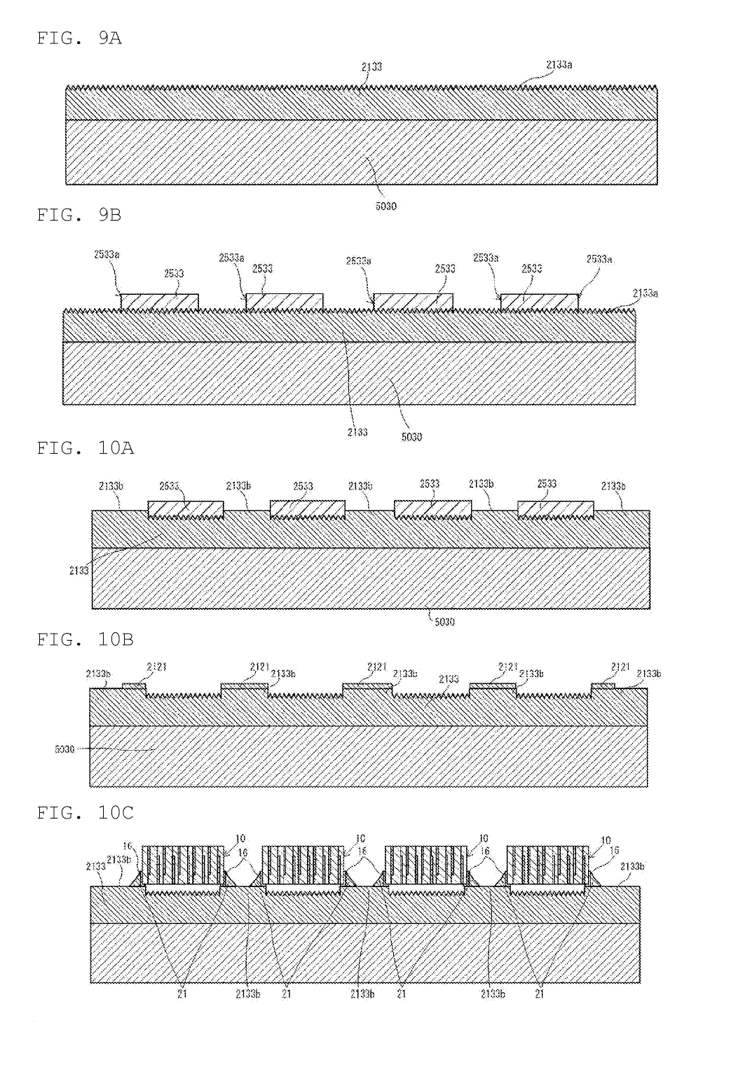

A thermoelectric conversion module according to the second embodiment is different from the thermoelectric conversion module 1 according to the first embodiment in that a substrate is not provided. As illustrated in FIGS. 7 and 8, a thermoelectric conversion module 2001 according to the present embodiment includes a plurality (four in FIG. 7) of thermoelectric conversion elements 10, a sealing member 2022, conductive portions 33, external electrodes 2034, and heat transfer parts 2027 and 2029. As illustrated in FIG. 8, the thermoelectric conversion module 2001 is used while the heat transfer part 2029 is in contact with a mounting surface HF of a heat generating object HS and the heat transfer parts 2027 are in contact with a heat sink 2030. In FIGS. 7 and 8, the same reference numerals as those in FIGS. 1 and 2 denote the respective same components as those in the first embodiment. The present embodiment will be described while a +Z direction in FIG. 8 is referred to as an upward direction and a −Z direction therein is referred to as a downward direction.

A plurality of conductive portions 33 are embedded in the sealing member 2022. The external electrodes 2034 are provided on respective lower surfaces of the conductive portions 33 positioned at opposite ends of the plurality of conductive portions 33 in the Y-axis direction.

The sealing member 2022 preferably has a rectangular parallelepiped outer shape and seals the plurality of thermoelectric conversion elements 10. The sealing member 2022 is preferably formed of a hardened body containing an epoxy resin and an inorganic filler as with the sealing member 22 according to the first embodiment.

The heat transfer parts 2027 are provided on a lower end portion of the sealing member 2022 to transfer heat from the sealing member 2022 to the heat sink 2030 outside the sealing member 2022. The heat transfer part 2029 is provided on an upper end portion of the sealing member 2022 to transfer heat from the heat generating object HS to the sealing member 2022. Each of the heat transfer parts 2027 is provided at a location falling within the perimeter of a respective thermoelectric conversion element 10 in the −Z direction (i.e., as viewed in an X-Y plane) on a lower surface of the sealing member 2022. The heat transfer part 2029 is provided so as to cover the entire upper surface of the sealing member 2022. The heat transfer parts 2027 and 2029 each are preferably formed of metal such as Cu, Ni, Al, or the like.

As described above, the thermoelectric conversion module 2001 according to the present embodiment includes the heat transfer part 2029 provided on the sealing member 2022 to transfer heat from the heat generating object HS to the sealing member 2022. In addition, the heat transfer parts 2027 are provided under the sealing member 2022 to transfer heat from the sealing member 2022 to the heat sink 2030. This improves not only efficiency of heat transfer from the heat generating object HS to the upper end portion of each of the thermoelectric conversion elements 10 via the heat transfer part 2029, but also efficiency of heat transfer from the lower end portion of each of the thermoelectric conversion elements 10 to the heat sink 2030 via the corresponding one of the heat transfer parts 2027. As a result, the temperature difference between the lower end portion and the upper end portion of each of the thermoelectric conversion elements 10 comes close to a temperature difference between the heat generating object HS and the heat sink 1030, so that output voltage increases accordingly to increase output voltage of the entire thermoelectric conversion module 2001.

The thermoelectric conversion module 2001 according to the second embodiment does not include a substrate and the plurality of thermoelectric conversion elements 10 are supported by the sealing member 2022 made of resilient resin material. This prevents the thermoelectric conversion module 2001 from being damaged even when a bending stress is applied to the entire thermoelectric conversion module 2001.

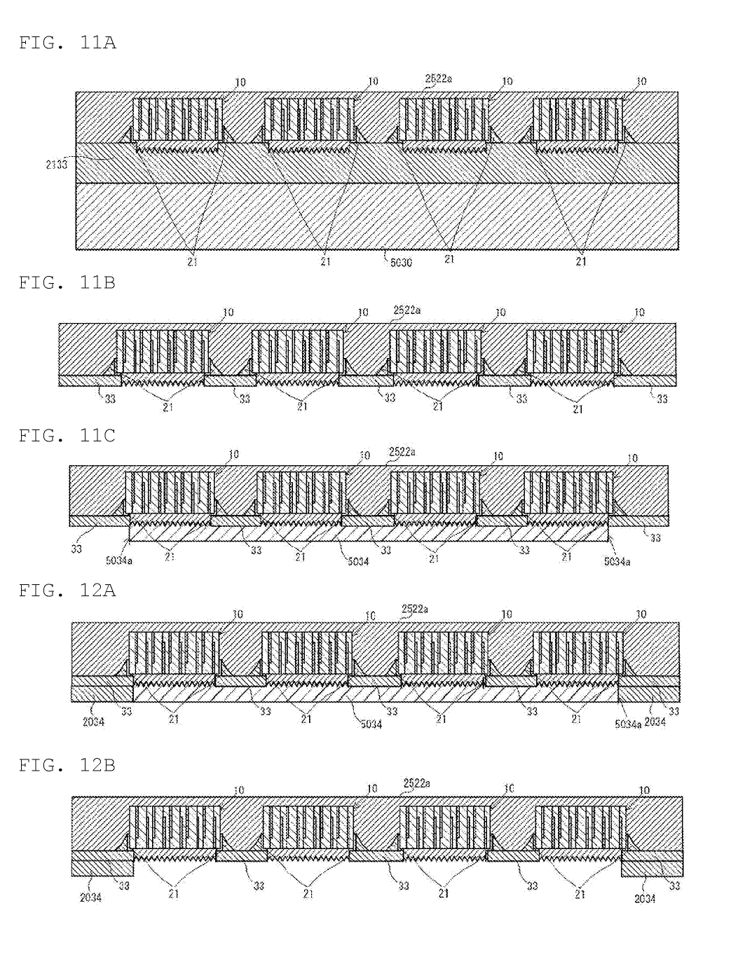

Next, a method for manufacturing the thermoelectric conversion module 2001 according to the second embodiment will be described with reference to FIGS. 9A, 9B, 10A, 10B, 10C, 11A, 11B, 11C, 12A, 12B, and 12C. In this manufacturing method, a foil-like metal foil 2133 as illustrated in FIG. 9A is prepared. The metal foil 2133 is provided in its upper surface (as viewed in FIG. 9A) with a roughened surface 2133a which acts as an adhesion prevention region to which a conductive paste does not adhere. The metal foil 2133 forms a base of the conductive portion 33 and is preferably made of metal such as Cu, Ni, Al, or the like. In consideration of work efficiency and cost of attaching operation to a support substrate 5030 described below and processing work such as etching, it is preferable to use Cu as the material of the metal foil 2133. A method for forming the roughened surface 2133a of the metal foil 2133 is not particularly limited, and it may be a chemical treatment such as etching, or a mechanical treatment such as a polishing treatment or a blast treatment. It is preferable that the metal foil 2133 has a thickness of 5 μm to 100 μm. The support substrate 5030 is made of glass or the like.

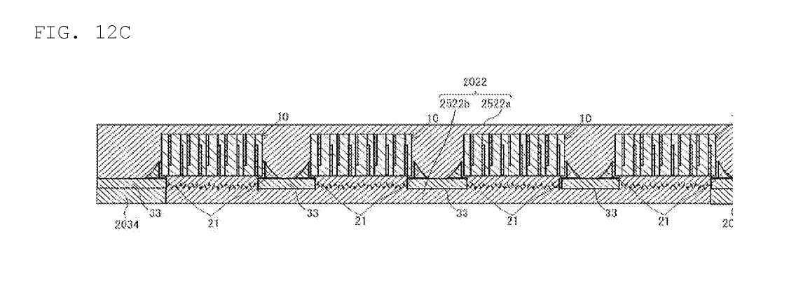

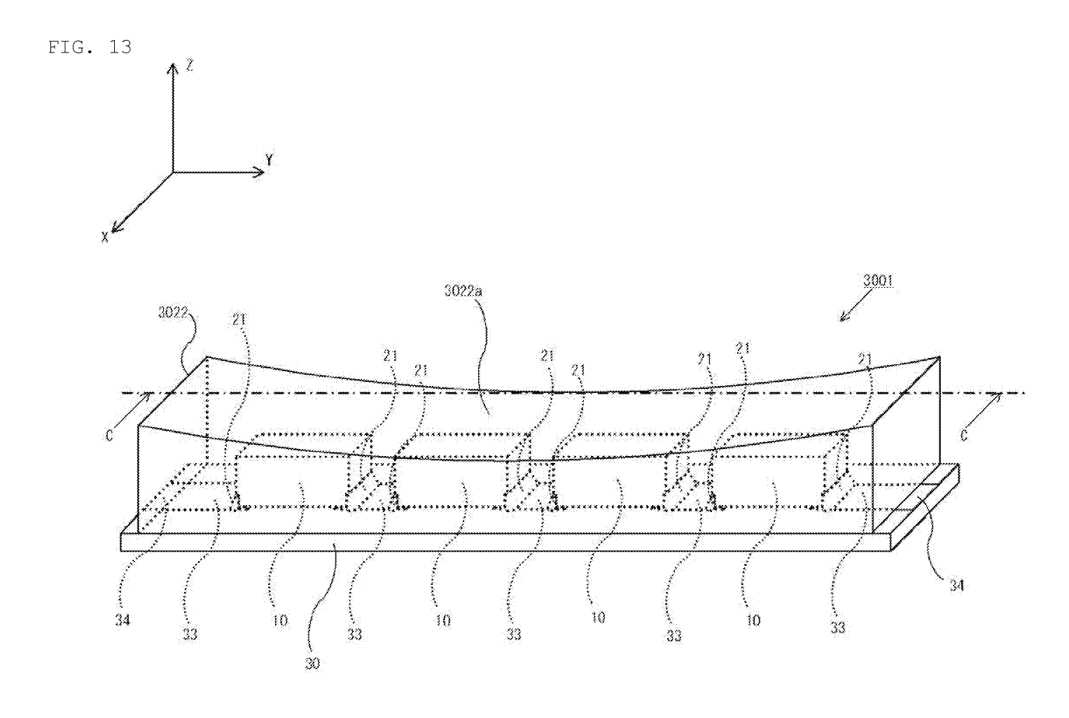

Next, as illustrated in FIG. 9A, the surface of the metal foil 2133 opposite to the roughened surface 2133a is attached to the support substrate 5030. Subsequently, as illustrated in FIG. 9B, masks 2533 for plating are formed on the metal foil 2133. The masks 2533 may be formed by performing exposure and development processing after a dry film resist is attached on the metal foil 2133 or by printing a resist using a well-known screen printing method, for example. As illustrated in FIG. 10A, each of the masks 2533 has a cavity 2533a in a portion where the metal layer 2133b is formed. It is preferable that the masks 2533 each have a thickness more than a thickness of the metal layer 2133b formed by a plating method.

Subsequently, as illustrated in FIG. 10A, a metal layer 2133b is formed on the metal foil 2133 using a plating method at a predetermined portion where the corresponding one of the plurality of conductive portions 33, positioned inside the cavity 2533a of the mask 2533, is to be formed. The upper surface of the metal layer 2133b is smoother than the roughened surface 2133a and constitutes a land region having better wettability of a conductive paste than the roughened surface 2133a. Accordingly, when a conductive paste is applied to the upper surface of the metal layer 2133b, the conductive paste stays on the upper surface of the metal layer 2133b due to its surface tension and is less likely to spread out to the roughened surface 2133a (after the masks 2533 have been removed as described below). The metal layer 2133b is preferably made of metal such as Cu, Ni, or the like. In consideration of electric conductivity and cost, it is preferable that the metal layer 2133b is made of Cu. As the plating method, the above-mentioned electrolytic plating method or electroless plating method can be used. The metal layer 2133b has a thickness that is set such that its upper surface is positioned higher than the apex of the roughened surface 2133a.

After metal layers 2133b are formed on the metal foil 2133, the masks 2533 are removed by immersing the support substrate 5030, the metal foil 2133, and the masks 2533 in a resist stripping solution such as a NaOH solution.

Subsequently, as illustrated in FIG. 10B, a conductive paste 2121 is applied to the upper surface of each of the metal layers 2133b using a well-known printing method. The conductive paste 2121 includes solder paste and the like.

Thereafter, each thermoelectric conversion element 10 is disposed such that opposite lateral ends of the thermoelectric conversion element 10 are brought into contact with respective adjacent metal layers 2133b which have been coated with the conductive paste 2121. A reflow process is then performed. As a result, a portion of the conductive paste 2121 creeps up a lateral side surface of each of the electrodes 16 of the thermoelectric conversion elements 10 to form conductive members 21 as illustrated in FIG. 10C. As a result, each electrode 16 is electrically connected to the upper surface (land area) of a respective metal layer 2133b by a respective conductive paste 2121. The upper surface of the metal layer 2133b is positioned higher than the apex of the roughened surface 2133a. As a result, the conductive paste 2121 stays on the upper surface of the metal layer 2133b due to surface tension and does not spread out to the roughened surface 2133a during the reflow process. Because the upper surface of the metal layer 2133b is positioned higher than the apex of the roughened surface 2133a a gap is generated between a lower surface of the thermoelectric conversion element 10 and the roughened surface 2133a.

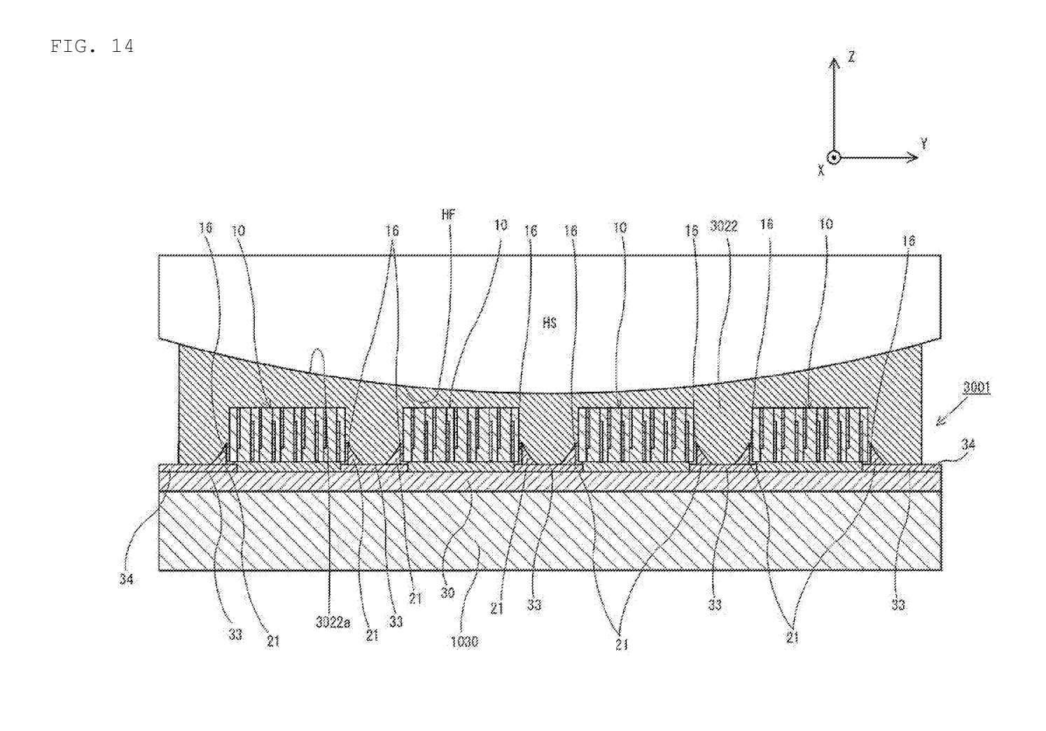

Subsequently, a structure composed of the substrate 5030, the metal foil 2133, and the thermoelectric conversion element 10 is placed in a metal mold for molding. Then, the metal mold is filled with sealing material using, for example, a transfer molding method or a potting method. The sealing material can be the same as the sealing material described in the first embodiment. As best shown in FIG. 11A, the sealing material covers the electromagnetic conversion element 10 and enters the gap between the lower surface of the thermoelectric conversion elements 10 and the roughened surfaces 2133a of the metal foil 2133. Then, the sealing material is heated to form a hardened body. In this way, an upper sealing portion (first sub-sealing portion) 2522a for covering an upper side of the metal foil 2133 is formed, as illustrated in FIG. 11A. Subsequently, the support substrate 5030 is peeled off from the metal foil 2133. Thereafter, a lower side of the metal foil 2133 is etched to remove a portion of the metal foil 2133 where the roughened surface 2133a is formed, thereby forming a plurality of conductive portions 33 as illustrated in FIG. 11B.

Next, a mask 5034 for plating is formed on a lower surface of the upper sealing portion 2522a, as illustrated in FIG. 11C. The mask 5034 has cavities 5034a at respective portions corresponding to the conductive portions 33 positioned at opposite ends of the thermoelectric conversion element array in the Y-axis direction and is formed by a method similar to that of the mask 2533 described above.

Subsequently, as illustrated in FIG. 12A, a metal layer is formed (preferably by a plating method) under each of the two outermost conductive portions 33 that are not covered with the mask 5034 to form external electrodes 2034. As the plating method, the above-mentioned electrolytic plating method or electroless plating method is used. As a result, a structure composed of the upper sealing portion 2522a, the conductive portion 33, and the external electrode 2034 is formed.

Then, the structure is immersed in a resist stripping solution such as a NaOH solution to remove the mask 5034, as illustrated in FIG. 12B.

Next, the structure is placed in a metal mold for molding, and the metal mold is filled with sealing material using, for example, a transfer molding method or a potting method. The sealing material is the same as the sealing material described in the first embodiment. Then, the sealing material is heated to form a hardened body. In this way, a lower sealing portion (second sub-sealing portion) 2522b is formed so as to cover a lower side of the conductive portion 33, where the external electrode 2034 is not formed, as illustrated in FIG. 12C. As a result, the sealing member 2022 composed of the upper sealing portion 2522a and the lower sealing portion 2522b is formed.

Subsequently, heat transfer parts 2027 are formed on the lower surface of the sealing member 2022, and a heat transfer part 2029 is formed on the upper surface of the sealing member 2022. The heat transfer parts 2027 and 2029 may be formed by applying a conductive paste using a well-known printing technique, or may be formed by a sputtering method or an evaporation method. Then the sealing member 2022 is divided into individual pieces by using a well-known dicing technique to complete a thermoelectric conversion module 2001.

As described above, in the method for manufacturing the thermoelectric conversion element 10 according to the second embodiment, the metal layer 2133b is formed on the upper surface of the metal foil 2133 on which the roughened surface 2133a is formed, and then the electrode 16 of the thermoelectric conversion element 10 is electrically connected to the upper surface of metal layer 2133b using the conductive paste 2121. Thus, the roughened surface 2133a provided around the metal layer 2133b can limit spreading out of the conductive paste 2121 applied on the upper surface of the metal layer 2133b on the upper surface of the metal foil 2133. This can prevent a short circuit occurring between the electrodes 16 of the thermoelectric conversion element 10 due to spreading out of the conductive paste 2121 on the upper surface of the metal foil 2133.

(Modification)

While two embodiments of the present invention are described above, the present invention is not limited to the structures of the above-described embodiments. For example, the present invention may be configured such that a sealing member 3022 has a curved contact surface 3022a, such as a thermoelectric conversion module 3001 illustrated in FIGS. 13 and 14. In FIGS. 13 and 14, the same reference numerals as those in FIGS. 1 and 2 are attached to the respective same components as those in the first embodiment. The thermoelectric conversion module 3001 enables the contact surface 3022a to be in surface contact with a mounting surface HF even when the mounting surface HF of the thermoelectric conversion module 3001 in the heat generating object HS is curved as illustrated in FIG. 14. For example, when a heat generating object HS is a cylindrical drain pipe, a radius of curvature R of the contact surface 3022a of the sealing member 3022 may be selected so as to coincide with an outer circumference radius of the drain pipe being the heat generating object HS.

This structure enables the contact surface 3022a of the sealing member 3022 to be in surface contact with the mounting surface HF even when the mounting surface HF of the heat generating object HS is curved. As a result, heat transfer efficiency from the heat generating object HS to the thermoelectric conversion element 10 is increased to increase power generation efficiency of the thermoelectric conversion module 3001.

In the method for manufacturing the thermoelectric conversion module 1 or 2001 according to the corresponding one of the embodiments, a conductive adhesive containing thermosetting resin may be used as the conductive paste. In this case, after the thermoelectric conversion elements 10 are disposed such that the electrodes 16 of each thermoelectric conversion element 10 is brought into contact with a conductive portion 33 and a portion coated with the conductive adhesive on an upper surface of a metal layer 2133b, heat treatment for curing the conductive adhesive may be performed.

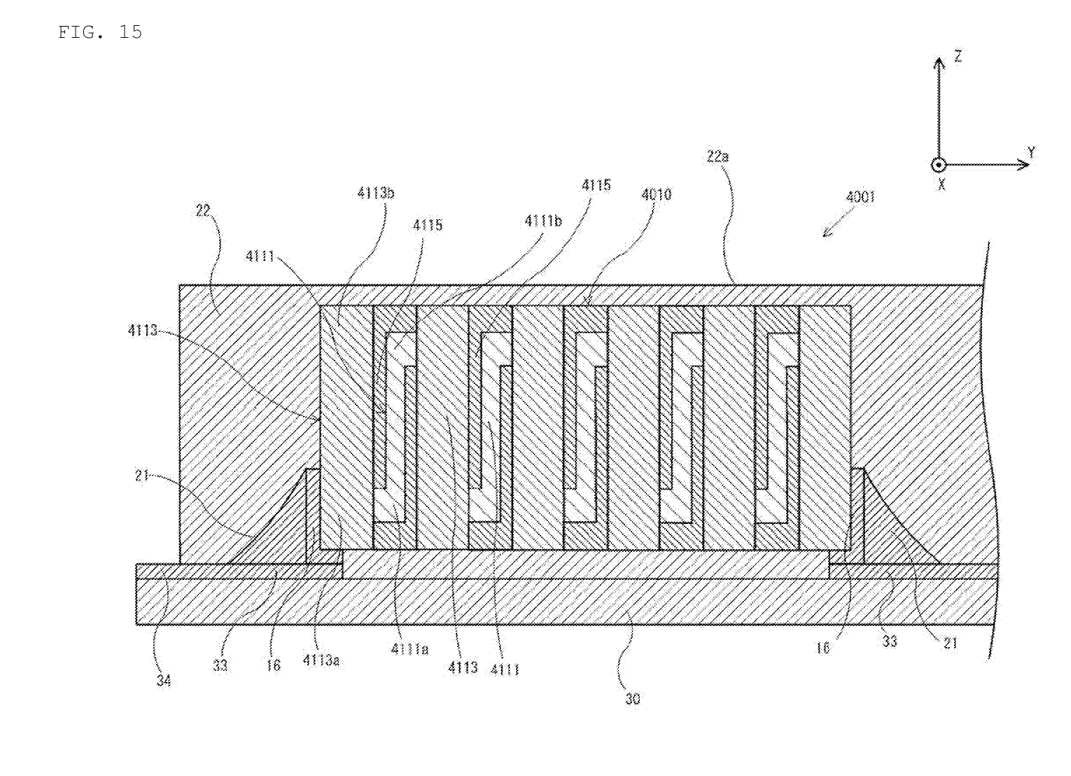

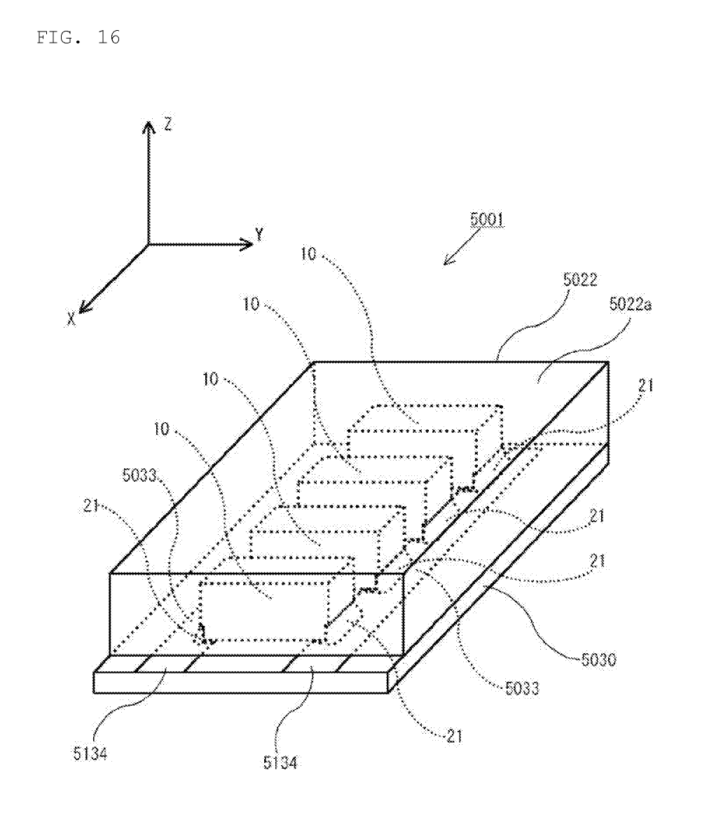

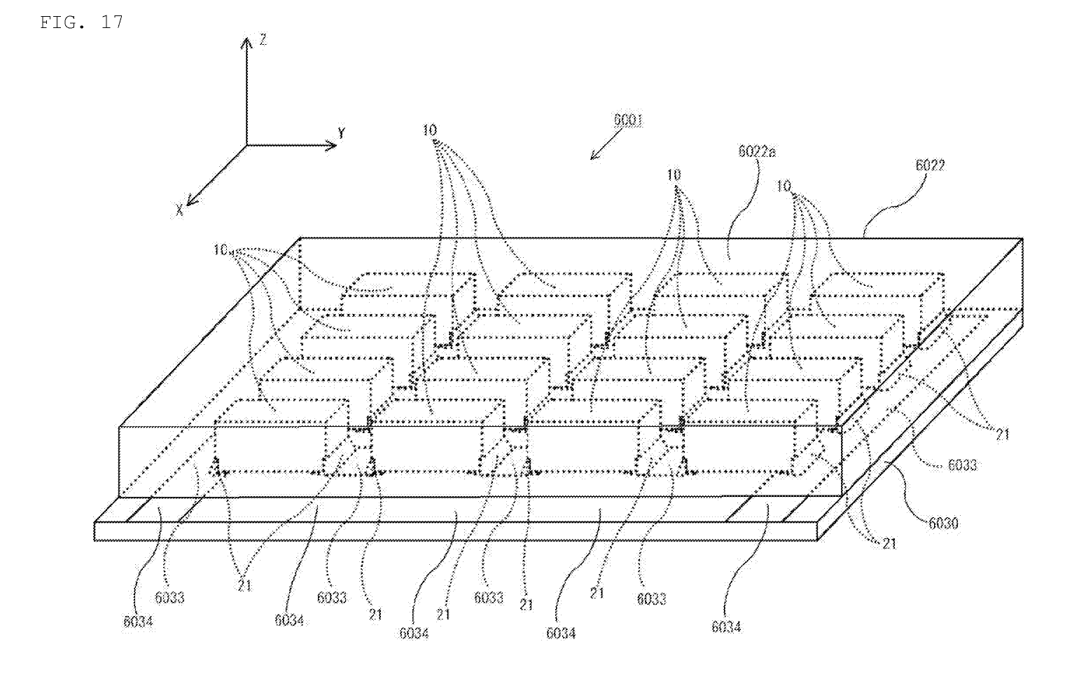

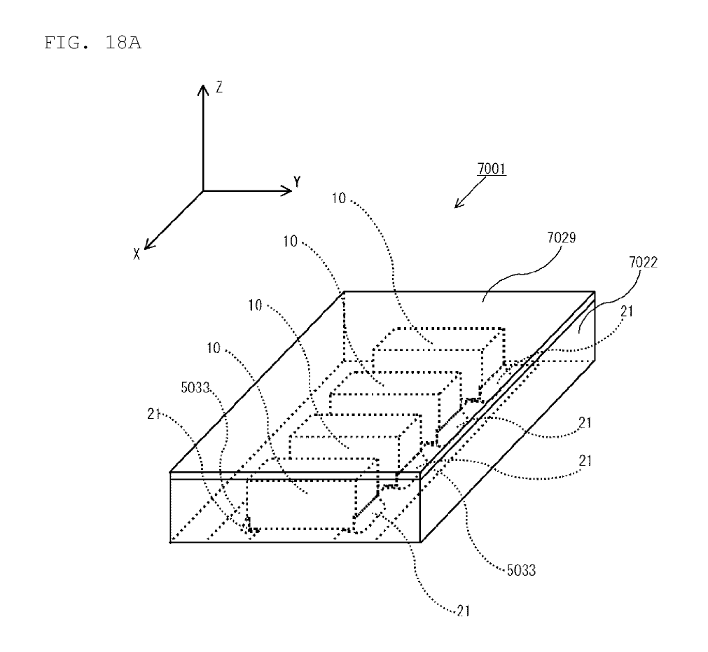

In the foregoing embodiments (thermoelectric conversion modules 1 and 2001) the thermoelectric conversion elements 10 include second thermoelectric conversion parts 111 which are disposed at respective opposite ends in the Y-axis direction of the thermoelectric conversion element 10 as shown, by way of example, in FIG. 3, and an end surface of those two second thermoelectric conversion parts 111 is exposed. However, the thermoelectric conversion element provided in each of the thermoelectric conversion modules 1 and 2001 is not limited to this structure. For example, there may be provided a thermoelectric conversion element 4010 in which a plurality of first thermoelectric conversion parts 4113 are disposed at respective opposite ends of the thermoelectric conversion element 4010 in the Y-axis direction, and insulator layers 4115 are disposed to cover all upper and lower end portions of the second thermoelectric conversion parts 4111 in a direction orthogonal to the Y-axis direction as shown in the thermoelectric conversion module 4001 illustrated in FIG. 15. In FIG. 15, the same reference numerals as those in FIG. 3 are attached to the respective same components as those in the first embodiment.

The plurality of first thermoelectric conversion parts 4113 and the plurality of second thermoelectric conversion parts 4111 are alternately disposed (i.e., alternate) and are bonded in the Y-axis direction. The first thermoelectric conversion part 4113 and the second thermoelectric conversion part 4111 are bonded to each other in a part of a surface of each of the first thermoelectric conversion part 4113 and the second thermoelectric conversion part 4111 in the Y-axis direction, and the insulator layer 4115 is interposed between the first thermoelectric conversion part 4113 and the second thermoelectric conversion part 4111 in a region other than the part of the surface in the Y-axis direction. Specifically, the second thermoelectric conversion part 4111 includes a lower end portion 4111a that is bonded to a lower end portion 4113a of the first thermoelectric conversion part 4113 adjacent to the second thermoelectric conversion part 4111 in the −Y direction. In addition, the second thermoelectric conversion part 4111 includes an upper end portion 4111b that is bonded to an upper end portion 4113b of the first thermoelectric conversion part 4113 adjacent to the second thermoelectric conversion part 4111 in the +Y direction. The first thermoelectric conversion part 4113 is made of N-type oxide thermoelectric conversion material, as with the first thermoelectric conversion part 113 described in the first embodiment. The second thermoelectric conversion part 4111 is made of P-type metal thermoelectric conversion material, as with the second thermoelectric conversion part 111 described in the first embodiment.

The insulator layer 4115 is interposed between the first thermoelectric conversion part 4113 and the second thermoelectric conversion part 4111, being adjacent to each other in the Y-axis direction. The insulator layer 4115 is made of oxide insulator material having electrical insulation properties, as with the insulator layer 115 described in the first embodiment.

According to this structure, the insulator layers 4115 are disposed to cover the entire end portions of the second thermoelectric conversion part 4111 in the Z-axis direction. The first thermoelectric conversion part 4113 is made of oxide thermoelectric conversion material that is chemically stable against corrosive gas such as hydrogen sulfide, and the insulator layer 4115 is made of oxide insulator material that is chemically stable against corrosive gas such as hydrogen sulfide. As a result, when the thermoelectric conversion module 4001 is used in an environment where corrosive gas is present, for example, the metal thermoelectric conversion material forming the second thermoelectric conversion part 4111 is prevented from chemically reacting with the corrosive gas to form impurities in the second thermoelectric conversion part 4111. This suppresses deterioration of the second thermoelectric conversion part 4111 even when the corrosive gas existing around the thermoelectric conversion module 4001 passes through the sealing member 22.

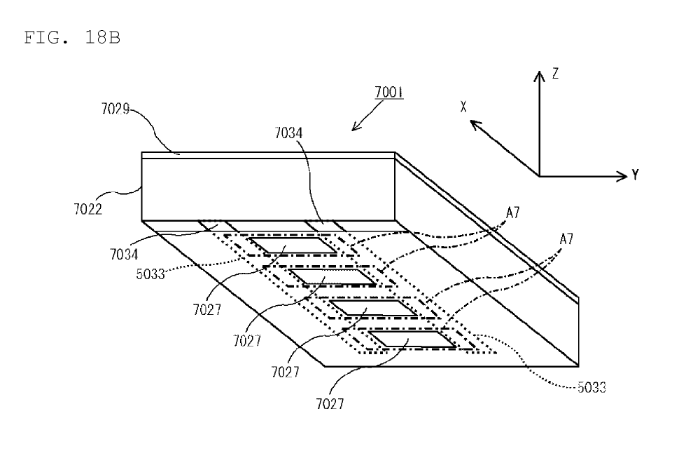

In each of the embodiments, there is described an example of the thermoelectric conversion module 1 in which the plurality of thermoelectric conversion elements 10 is connected in series via the respective conductive portions 33. However, the present invention is not limited to this example, and a plurality of thermoelectric conversion elements 10 may be connected in parallel like a thermoelectric conversion module 5001 illustrated in FIG. 16, for example. In this thermoelectric conversion module 5001, the plurality of thermoelectric conversion elements 10 is mutually connected to two conductive portions 5033 formed on a substrate 5030. The plurality of thermoelectric conversion elements 10 is sealed by a sealing member 5022. The sealing member 5022 is provided on its upper side with a contact surface (heated portion) 5022a that is to be thermally coupled to a heat generating object HS. The two conductive portions 5033 extend to respective external electrodes 5134 each exposed in a portion of the substrate 5030, being not covered with the sealing member 5022.

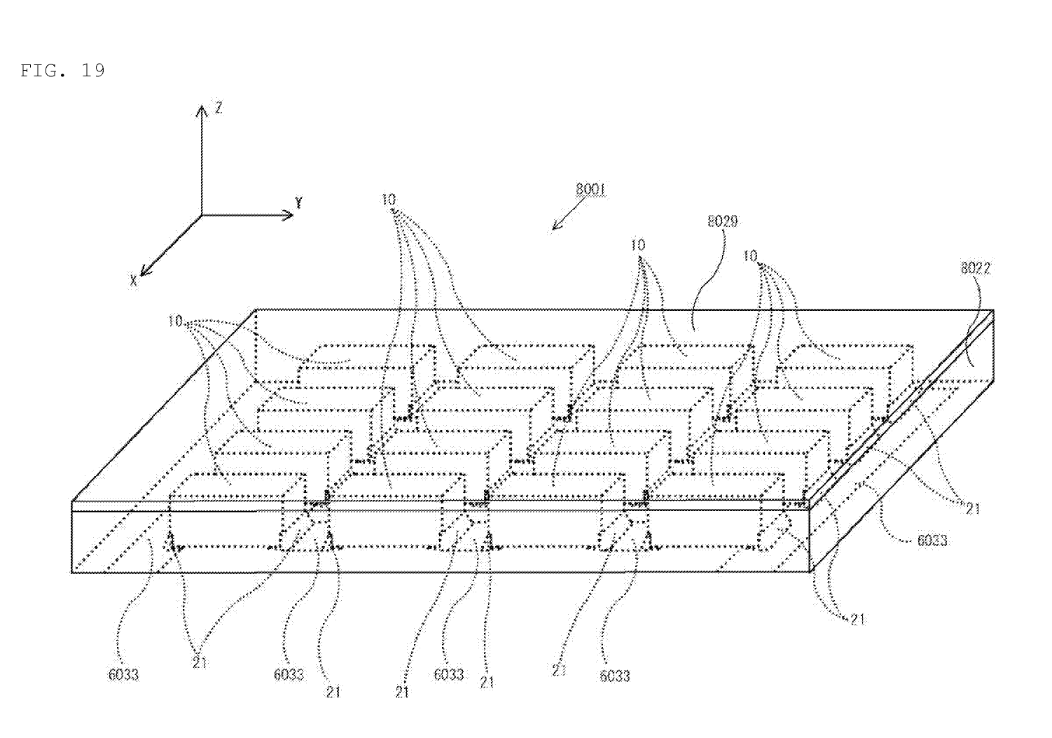

In addition, four series circuits formed of four thermoelectric conversion elements 10 connected in series may be connected in parallel like a thermoelectric conversion module 6001 illustrated in FIG. 17. In the thermoelectric conversion module 6001, sixteen thermoelectric conversion elements 10 constituting the above four series circuits are arranged in a two-dimensional matrix, and sealed by a sealing member 6022. The thermoelectric conversion elements 10 are electrically connected to the corresponding other thermoelectric conversion elements 10 via corresponding conductive portions 6033 formed on a substrate 6030. The sealing member 6022 is provided on its upper side with a contact surface (heated portion) 6022a that is to be thermally coupled to a heat generating object HS. The two conductive portions 6033 disposed at respective opposite ends in the Y-axis direction while extending in the X-axis direction extend to respective external electrodes 6034 each exposed in a portion of the substrate 6030, being not covered with the sealing member 6022.

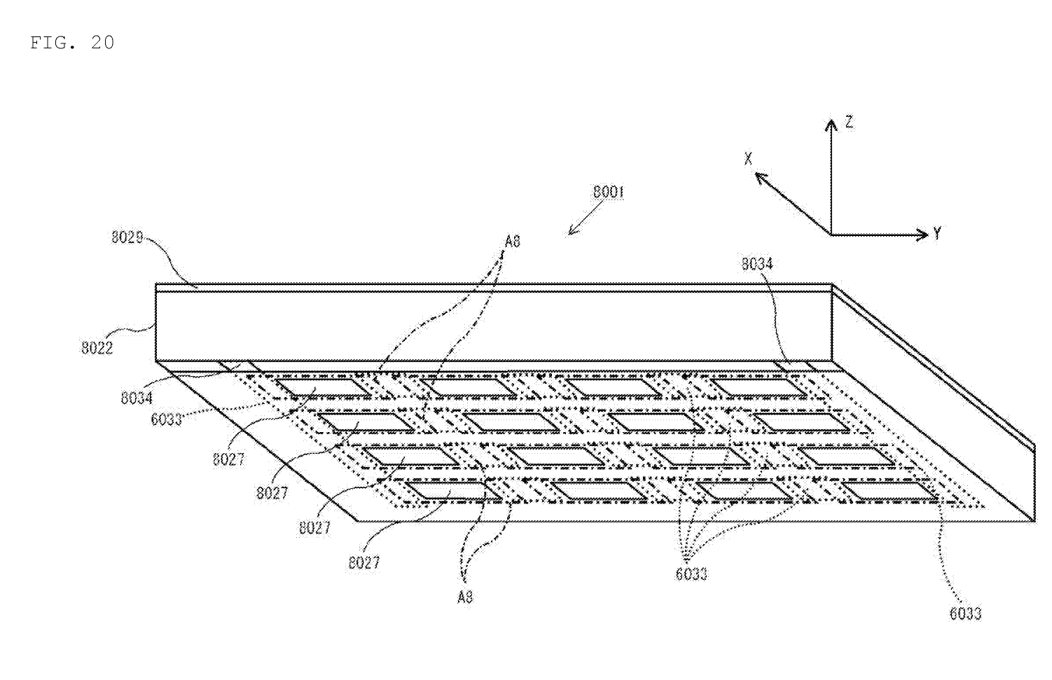

Alternatively, a plurality of thermoelectric conversion elements 10 may be connected in parallel without a substrate, like a thermoelectric conversion module 7001 illustrated in FIGS. 18A and 18B. In this thermoelectric conversion module 7001, a plurality of thermoelectric conversion elements 10 is sealed by a sealing member 7022, and is mutually connected to two conductive portions 5033 embedded in the sealing member 7022. The sealing member 7022 is provided on its upper side with a heat transfer part 7029 that is to be thermally coupled to a heat generating object (not illustrated) that is to be brought into contact with the upper side of the sealing member 7022. In addition, the sealing member 7022 is also provided on its lower side with heat transfer parts 7027 for transferring heat to a heat sink (not illustrated) and the like that are to be brought into contact with the lower side of the sealing member 7022, as illustrated in FIG. 18B. The heat transfer parts 7027 are provided inside a projection region A7 of the thermoelectric conversion element 10 in the −Z direction on a lower surface of the sealing member 7022. The two conductive portions 5033 extend to respective external electrodes 7034 each exposed on the lower side of the sealing member 6022.

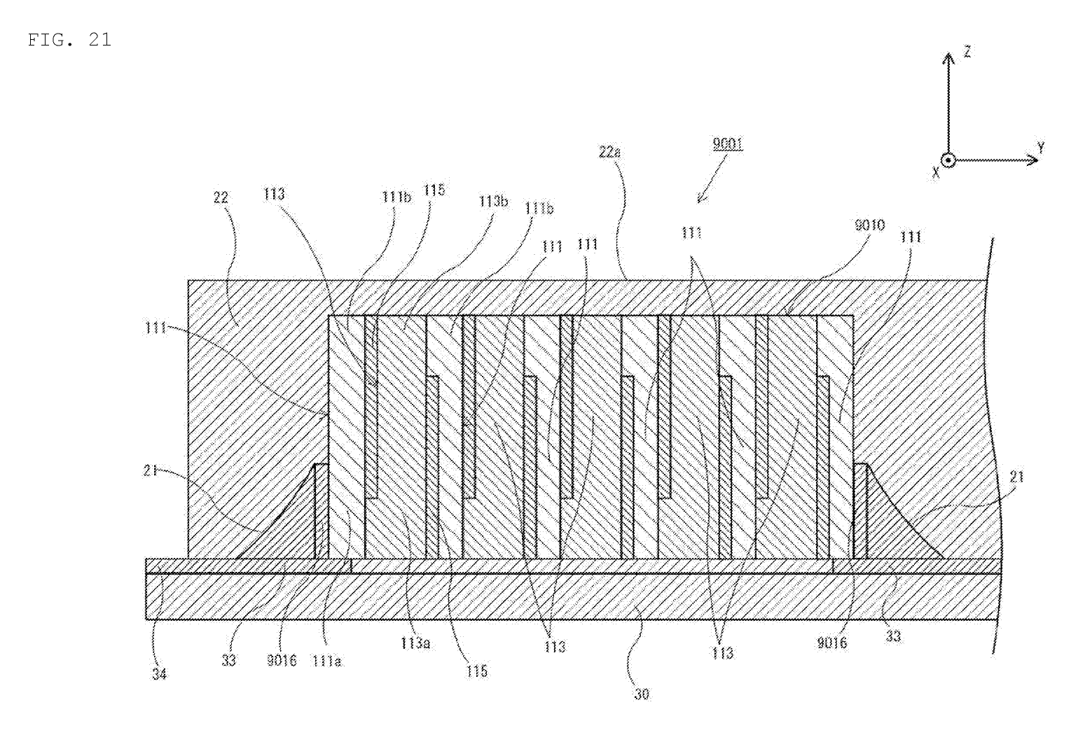

In addition, four series circuits formed of four thermoelectric conversion elements 10 connected in series may be connected in parallel without a substrate, like a thermoelectric conversion module 8001 illustrated in FIGS. 19 and 20. In the thermoelectric conversion module 8001, sixteen thermoelectric conversion elements 10 constituting the above four series circuits are arranged in a two-dimensional matrix, and sealed by a sealing member 8022. The thermoelectric conversion elements 10 are electrically connected to the corresponding other thermoelectric conversion elements 10 via corresponding conductive portions 6033 embedded in the sealing member 8022. The sealing member 8022 is provided on its upper side with a heat transfer part 8029 that is to be thermally coupled to a heat generating object (not illustrated) that is to be brought into contact with the upper side of the sealing member 8022. In addition, the sealing member 8022 is also provided on its lower side with heat transfer parts 8027 for transferring heat to a heat sink (not illustrated) and the like that are to be brought into contact with the lower side of the sealing member 8022, as illustrated in FIG. 20. The heat transfer parts 8027 are provided inside a projection region A8 of the thermoelectric conversion elements 10 in the −Z direction on a lower surface of the sealing member 8022. The two conductive portions 6033 disposed at respective opposite ends in the Y-axis direction while extending in the X-axis direction extend to respective external electrodes 8034 each exposed on the lower side of the sealing member 8022.

In the first embodiment, there is described an example in which the electrode 16 of the thermoelectric conversion element 10 has an L-shaped section covering a part of a surface of the second thermoelectric conversion part 111 on its +Y direction side or a surface thereof on its −Y direction side, and a part of a lower end surface thereof. However, the shape of the electrode 16 is not limited to this. For example, there may be provided a thermoelectric conversion element 9010 in which an electrode 9016 is provided to cover a part of a surface of the second thermoelectric conversion part 111 of on its +Y direction side or a part of a surface thereof on its −Y direction side, and not to cover a lower end surface of the second thermoelectric conversion part 111, like the thermoelectric conversion module 9001 illustrated in FIG. 21. In FIG. 21, the same reference numerals as those in FIG. 3 are attached to the respective same components as those in the first embodiment. The thermoelectric conversion module 9001 according to the present modified example also has similar operational effects to those of the first embodiment.

In the second embodiment, there is described the method for manufacturing the thermoelectric conversion module 2001 using the metal foil 2133 provided on its one surface with the roughened surface 2133a to be an adhesion prevention region, however, this adhesion prevention region of the metal foil is not limited to a region where a roughened surface is formed. The adhesion preventing region may be formed of a region where an oxide film is formed. Alternatively, the adhesion preventing region may be formed of a region where a Sn-based material layer made of Sn, or a Sn alloy or the like is formed.

In the second embodiment, there is described an example in which the heat transfer parts 2027 and 2029 each are formed of metal, however, the material forming the heat transfer parts 2027 and 2029 is not limited to metal. For example, the heat transfer parts 2027 and 2029 each may be made of insulator material having a relatively high thermal conductivity, such as AlN, SiN, Al2O3, or the like.

In each of the embodiments and the modified examples described above, there is described an example in which the thermoelectric conversion modules 1, 2001, 3001, and 4001 each are provided with a so-called laminated-type thermoelectric conversion element 10, however, the structure of the thermoelectric conversion element is not limited to a laminated-type. For example, the thermoelectric conversion modules 1 and 2001 each may include a so-called 7c-type thermoelectric conversion element in which columnar first thermoelectric conversion parts each made of N-type oxide thermoelectric conversion material, and columnar second thermoelectric conversion parts each made of P-type metal thermoelectric conversion material, are alternately disposed.

While the embodiments and the modified examples of the present invention (including those described in the description, the same applies below) are described above, the present invention is not limited to these. The present invention includes those in which the embodiments and the modified examples are appropriately combined, and those in which the embodiments and the modified examples are appropriately modified.

The present application is based on Japanese Patent Application No. 2016-071966 filed on Mar. 31, 2016. In the present specification, the specification, the scope of claims, and the drawings of Japanese Patent Application No. 2016-071966 are incorporated by reference in their entirety.

### DESCRIPTION OF REFERENCE SYMBOLS

1, 2001, 3001, 4001, 5001, 6001, 7001, 8001, 9001: thermoelectric conversion module
10, 4010, 9010: thermoelectric conversion element
16, 9016: electrode
21: conductive member
22, 522, 2022, 3022, 5022, 6022, 7022, 8022: sealing member
22a, 3022a, 5022a, 6022a: contact surface
30, 5030, 6030: substrate
33, 5033, 6033: conductive portion
34, 2034, 5134, 6034, 7034, 8034: external electrode
111, 4111: second thermoelectric conversion part
111a, 113a, 4111a, 4113a: lower end portion
111b, 113b, 4111b, 4113b: upper end portion
113, 4113: first thermoelectric conversion part
115, 4115: insulator layer
133, 2133: metal foil
512: metal layer
2121: conductive paste
522a: groove
2533, 5034: mask
2533a, 5034a: cavity
2027, 2029, 7027, 7029, 8027, 8029: heat transfer part
1030, 2030: heat sink
2133a: roughened surface
2133b: metal layer
2522a: upper sealing portion
2522b: lower sealing portion
5030: support substrate
A7, A8: projection region
HF: mounting surface
HS: heat generating object

1. A thermoelectric conversion module comprising:
a plurality of thermoelectric conversion elements, each of the plurality of thermoelectric conversion elements comprising a laminated body having first and second opposing main surfaces which are spaced from each other along a first direction and first and second opposing end surfaces which are spaced from each other along a second direction, the second direction being perpendicular to the first direction, each of the laminated bodies comprising a plurality of first and second thermoelectric conversion parts which alternate with one another along the first direction, each of the first and second thermoelectric conversion parts having opposed first and second end surfaces which are spaced apart along the second direction; and
a sealing member sealing the plurality of thermoelectric conversion elements, the sealing member including portions located on at least some of the first end surfaces of the first and second thermoelectric conversion parts and portions located on at least some of the second end surfaces of the first and second thermoelectric conversion parts.

2. The thermoelectric conversion module according to claim 1, wherein an external surface of the sealing member has a non-planar shape allowing surface contact with a heat-generating object.

3. The thermoelectric conversion module according to claim 1, further comprising a heat transfer element provided on one of the first and second sealing member portions to either transfer heat from a heat generating object to the sealing member or to transfer heat from the sealing member to a heat radiating member.

4. The thermoelectric conversion module according claim 1, wherein the sealing member is a hardened body made of an epoxy resin.

5. The thermoelectric conversion module according to claim 4, wherein the hardened body further contains an inorganic filler.

6. The thermoelectric conversion module according to claim 1, wherein adjacent first and second thermoelectric parts each define a respective thermoelectric conversion part pair, each thermoelectric conversion part pair including a respective first thermoelectric conversion part and a respective second thermoelectric conversion part, a joint surface of the first thermoelectric part of the pair facing a joint surface of the second thermoelectric part of the pair, and the thermoelectric module further comprising a plurality of insulator layers, each insulator layer being associated with a respective thermoelectric conversion part pair, each insulator being located between a first portion of the facing joint surfaces of the first and second thermoelectric conversion parts of its respective thermoelectric conversion part pair, a second portion of the facing joint surfaces of the first and second thermoelectric conversion parts of each thermoelectric part pair being directly joined to one another.

7. The thermoelectric conversion module according to claim 6, wherein each second thermoelectric conversion part has an end face opposing the first or second end surface of the laminated body with a portion of a respective one of insulator layers covering the end face and being located between the end face and the first or second end surface that the end face opposes.

8. The thermoelectric conversion module according to claim 7, wherein each of the second thermoelectric conversion parts is made of a metal thermoelectric conversion material.

9. The thermoelectric conversion module according to claim 8, wherein:
each of the first thermoelectric conversion parts is made of oxide thermoelectric conversion material; and
each of the insulator layers is made of oxide insulator material.

10. The thermoelectric conversion module of claim 1, wherein each of the first and second thermoelectric conversion parts is planar in shape and the plane of each of the first and second thermoelectric conversion parts lies in a plane that is perpendicular to the first direction.

11. The thermoelectric conversion module of claim 1, wherein the sealing member includes portions located on all of the first and second end surfaces of the first and second thermoelectric conversion parts.

12. The thermoelectric conversion module of claim 3, wherein the heat transfer member is formed of metal

13. The thermoelectric conversion module of claim 3, wherein a respective heat transfer member is provided for each of the thermoelectric conversion elements.

14. The thermoelectric conversion module of claim 13, wherein each of the heat transfer members is formed of metal.

15. A method for manufacturing a thermoelectric conversion module, comprising the steps of:
preparing a metal foil having first and second opposed surfaces, the first surface of the metal foil being provided with an adhesion prevention region to which a conductive paste does not adhere;
attaching the second surface of the metal foil to a support substrate;
forming a plurality of land regions in the first surface of the metal foil, each land region having a wettability relative to the conductive paste that is better than the wettability of the adhesion prevention region of the metal foil, at locations where conductive parts are to be formed;
electrically connecting an electrode of a thermoelectric conversion element to one of the land regions using the conductive paste;
forming a first sub-sealing portion which covers at least part of the first surface of the metal foil;
removing the support substrate from the second surface of the metal foil;
forming the conductive parts by processing the second side of the metal foil such that the conductive parts each have first and second opposed surfaces, the first sub-sealing portion covering the first surface of the conductive parts;
forming external electrodes on the second surface of two of the plurality of conductive parts; and
forming a second sub-sealing portion covering the second surface of each of the conductive parts except for the two conductive parts on which the external electrodes are formed.

16. A method according to claim 15, wherein the electrode of the thermoelectric element is a first electrode and wherein the method further comprises electrically connecting a second electrode of the thermoelectric conversion element to a second of the land regions.
